(19) United States
(12) Patent Application Publication
(10) Pub. No.: US 2014/0187912 A1
(43) Pub. Date: Jul. 3, 2014

(54) POSITIONING DEVICE, IMAGE PROJECTING SYSTEM AND METHOD FOR OVERLAPPING IMAGES

(71) Applicant: METAL INDUSTRIES RESEARCH&DEVELOPMENT CENTRE, Kaohsiung (TW)

(72) Inventors: WEI-CHING WANG, Kaohsiung City (TW); BING-FENG HUANG, Kaohsiung City (TW); WEI-TE CHEN, Changhua County (TW); PEI-YUAN LEE, Taichung City (TW); KAI-CHE LIU, Kaohsiung City (TW); MIN-LIANG WANG, Taichung City (TW)

(73) Assignee: METAL INDUSTRIES RESEARCH&DEVELOPMENT CENTRE, Kaohsiung (TW)

(21) Appl. No.: 14/098,673

(22) Filed: Dec. 6, 2013

(30) Foreign Application Priority Data
Dec. 27, 2012 (TW) 101150508

(51) Int. Cl. G01R 33/48

(52) U.S. Cl. CPC G01R 33/4812
USPC 600/411

(57) ABSTRACT

A positioning device, an image projecting system and a method for overlapping images are provided. The positioning device is applied to a Computed Tomography process and a Magnetic Resonance Imaging process. The positioning device includes a patch and a positioning mark. The positioning mark is adapted to be mounted on the patch, and includes a Computed Tomography mark and a Magnetic Resonance Imaging mark.

### CROSS-REFERENCE TO RELATED APPLICATION

This application claims the benefit of Taiwan Patent Application No. 101150508, filed on Dec. 27, 2012, which is hereby incorporated by reference for all purposes as if fully set forth herein.

### BACKGROUND OF THE INVENTION

1. Field of Invention

The present invention relates to a positioning device, an image projecting system and a method for overlapping images, and more particularly to a positioning device, an image projecting system and a method for overlapping images, wherein the positioning device is attached on a skin of a human body, a Computed Tomography process and a Magnetic Resonance Imaging process are operated, an overlapped image is gotten by the method for overlapping a Computed Tomography image with a Magnetic Resonance Imaging image, and finally the overlapped image is projected to the skin by the image projecting system.

2. Related Art

In the past, a medical diagnosis is still based on physiological anatomy images of an X-ray radiography process and a supersonic wave imaging process. The medical diagnosis starts to focus on functional images until Magnetic Resonance Imaging (MRI) technology is fully developed in 1990s. Thus, medical images have the requirement and development that are higher than those of a physiological structure.

For the past few years, a Computed Tomography (CT) technology is developed so as to detect a target organ in the multi-direction and then generate images. After the images are re-combined, a three-dimensional image is gotten.

Recently, according to a common medical diagnosis for high level surgical operation, the image information of the Magnetic Resonance Imaging process and the image information of the Computed Tomography process are only used by a doctor to find a cause of organic lesions and carry out a preoperative route plan. However, in a clinical application, it is found that the doctor greatly needs the image information. Particularly, the Computed Tomography process can provide the geometric information of hard tissues and soft tissues, and Magnetic Resonance Imaging process can provide the functional images of nerve and water molecule, etc. According to more and more surgical operation, the Magnetic Resonance Imaging image and the Computed Tomography image are requested simultaneously to become the re-establish image information.

Therefore, it is necessary to provide an image projecting system and a method for overlapping images, wherein according to a single patient an overlapped image is gotten by accurately overlapping a Computed Tomography image with a Magnetic Resonance Imaging image so as to be capable of solving the above problems.

### SUMMARY OF THE INVENTION

An objective of the present invention is to provide a positioning device, an image projecting system and a method for overlapping images, wherein according to a single patient an overlapped image is gotten by accurately overlapping a Computed Tomography image with a Magnetic Resonance Imaging image.

To achieve the above objective, the present invention provides a positioning device applied to a Computed Tomography process and a Magnetic Resonance Imaging process. The positioning device includes a patch and a positioning mark. The positioning mark is adapted to be mounted on the patch, and includes a Computed Tomography mark and a Magnetic Resonance Imaging mark.

The present invention further provides an image projecting system including an image overlapping device and a projecting device. The image overlapping device is adapted to overlap a Magnetic Resonance Imaging image with a Computed Tomography image so as to get an overlapped image, wherein al least two images of the Magnetic Resonance Imaging mark are aligned with al least two images of the Computed Tomography mark. The projecting device is electrically connected to the image overlapping device for projecting the overlapped image on a skin.

The present invention further provides a method for overlapping images including the following steps of: attaching at least two positioning devices on a skin, wherein each positioning device comprises a Computed Tomography mark and a Magnetic Resonance Imaging mark; utilizing a Computed Tomography process to take a photo so as to get a Computed Tomography image, wherein the Computed Tomography image comprises at least two images of the Computed Tomography mark; utilizing a Magnetic Resonance Imaging process to take a photo so as to get a Magnetic Resonance Imaging image, wherein the Magnetic Resonance Imaging image comprises at least two images of the Magnetic Resonance Imaging mark; and aligning the images of the Magnetic Resonance Imaging mark with the images of the Computed Tomography mark for overlapping the Magnetic Resonance Imaging image with the Computed Tomography image so as to form an overlapped image.

The positioning device, the image projecting system and the method for overlapping images according to the present invention can provide the surgical doctor with the medical requirement of preoperative simulated image and operative augmented reality of that the overlapped image and the patch located on the skin are overlapped. Thus, according to the surgical doctor, the surgical operation performed by watching the image in the screen can be replaced with the surgical operation performed by directly positioning and projecting the overlapped image on the skin of the human body, whereby the preoperative simulated image can be accurately projected to the real affected part of a patient's body in the surgical operation.

To make the above and other objectives, features, and advantages of the present invention more comprehensible, detailed illustration is provided below with reference to the accompanying drawings.

### BRIEF DESCRIPTION OF THE DRAWINGS

The present invention will become more fully understood from the detailed description given herein below for illustration only, and thus are not limitative of the present invention, and wherein:

FIG. 1 is a cross-sectional view of a positioning device according to the first embodiment of the present invention;

FIG. 2 is a cross-sectional view of a positioning device according to the second embodiment of the present invention;

FIG. 3 is a cross-sectional view of a positioning device according to the third embodiment of the present invention;

FIG. 4a is a schematic block diagram showing an image projecting system according to an embodiment of the present invention;

FIG. 4b is a schematic view showing a Magnetic Resonance Imaging image of the present invention;

FIG. 4c is a schematic view showing a Computed Tomography image of the present invention;

FIG. 4d is a schematic view showing an overlapped image of the present invention; and

FIG. 5 is a flow diagram of a method for overlapping images according to an embodiment of the present invention.

### DETAILED DESCRIPTION OF THE INVENTION

FIG. 1 is a cross-sectional view of a positioning device according to the first embodiment of the present invention. A positioning device 100 includes a patch 110 and a positioning mark 120. The positioning mark 120 includes a Computed Tomography mark 121 and a Magnetic Resonance Imaging mark 122. The Computed Tomography mark 121 includes a receiving space 121a, and the Magnetic Resonance Imaging mark 122 is located in the receiving space 121a.

The patch 110 has a screw hole 111. The positioning mark 120 further includes a screw portion 123, which is formed on the Computed Tomography mark 121. Thus, the positioning mark 120 is mounted on the patch 110 in a screwing manner by using the screw hole 111 and the screw portion 123. The Computed Tomography mark 121 and the screw portion 123 can be made of the same material and integrally formed. The Computed Tomography mark 121 can be made of titanium (Ti) metal material, high polymer material, ceramics material or combinations thereof. The Magnetic Resonance Imaging mark 122 can be made of water, oil or combinations thereof. The patch 110 can be a medical patch, which can be attached on a human skin so as to flexibly meet the need of a schedule of a surgical operation arranged by a hospital.

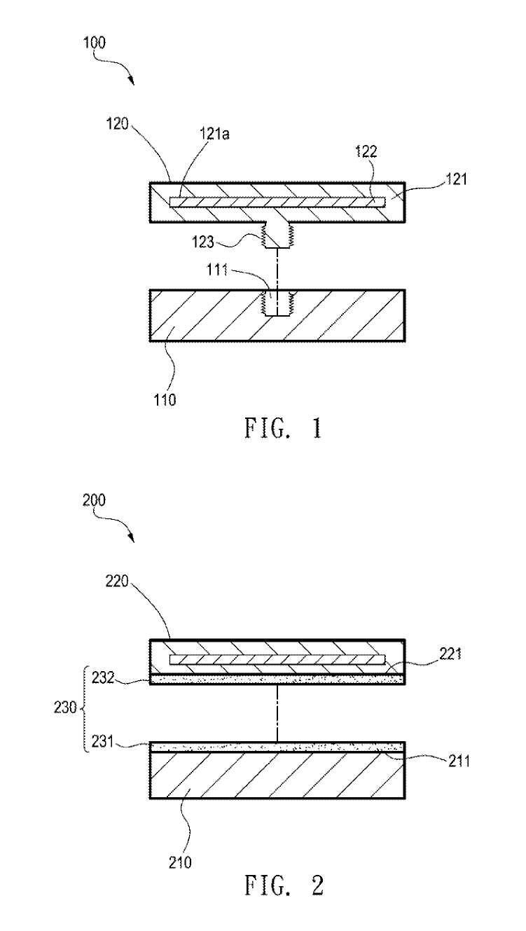

As shown in FIG. 2, it depicts a positioning device according to the second embodiment of the present invention. The positioning device 200 in the second embodiment is substantially similar to the positioning device 100 in the first embodiment, wherein the similar elements are designated with the same reference numerals. The difference between the positioning devices 200, 100 in the second and first embodiments is that: the mounting manner of the patch and the positioning mark.

The positioning device 200 further includes a demountable element 230 (which can be disassembled and assembled). The demountable element 230 can be mounted on an upper surface 211 of the patch 210 and/or a lower surface 221 of the positioning mark 220. The demountable element 230 can be an element for mounting the positioning mark on the patch in the screwing manner in the first embodiment. Or, the demountable element 230 can be an element for mounting the positioning mark on the patch in a snapping manner or an attaching manner. The element for mounting the positioning mark on the patch in the attaching manner can be double-sided tape, repetitively coated adhesive or Velcro. In this embodiment, the Velcro is used, for example. The demountable element 230 includes a first felt portion 231 and a second felt portion 232 of the Velcro. The first felt portion 231 of the Velcro is mounted on an upper surface 211 of the patch 210, and the second felt portion 232 of the Velcro is mounted on a lower surface 221 of the positioning mark 220. During the usage, the first felt portion 231 and the second felt portion 232 of the Velcro are adapted for mounting the positioning mark 220 and the patch 210 to each other in the attaching manner.

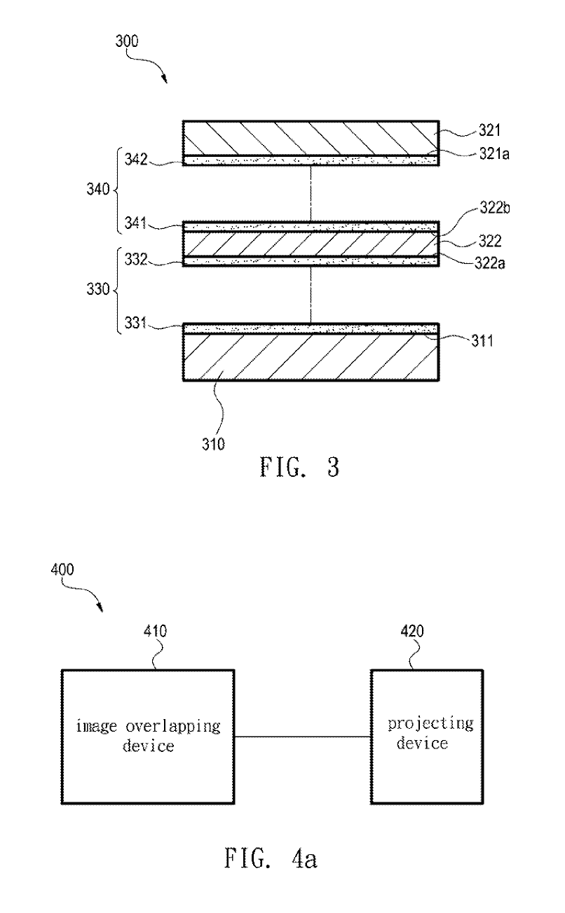

As shown in FIG. 3, it depicts a positioning device according to the third embodiment of the present invention. The positioning device 300 in the second embodiment is substantially similar to the positioning device 100 in the first embodiment, wherein the similar elements are designated with the same reference numerals. The difference between the positioning devices 300, 100 in the second and first embodiments is that: the design of the positioning mark.

The Magnetic Resonance Imaging mark 322 is disposed between the Computed Tomography mark 321 and the patch 310. The positioning device 300 further includes a first demountable element 330 and a second demountable element 340 (which both can be disassembled and assembled). The first demountable element 330 can be mounted on an upper surface 311 of the patch 310 and/or a lower surface 322a of the Magnetic Resonance Imaging mark 322. The second demountable element 340 can be mounted on an upper surface 322b of the Magnetic Resonance Imaging mark 322 and/or a lower surface 321a of the Computed Tomography mark 321.

The first demountable element 330 and the second demountable element 340 can be elements for mounting the positioning mark on the patch in the screwing manner in the first embodiment. Or, the first and second demountable elements 330, 340 can be elements for mounting the positioning mark on the patch in a snapping manner or an attaching manner. The elements for mounting the positioning mark on the patch in the attaching manner can be double-sided tape, repetitively coated adhesive or Velcro. In this embodiment, the Velcro is used, for example. The first demountable element 330 includes a first felt portion 331 and a second felt portion 332 of the Velcro. The second demountable element 340 includes a third felt portion 341 and a fourth felt portion 342 of the Velcro. The first felt portion 331 of the Velcro is mounted on the upper surface 311 of the patch 310, the second felt portion 332 of the Velcro is mounted on the lower surface 322a of the Magnetic Resonance Imaging mark 322, the third felt portion 341 of the Velcro is mounted on the upper surface 322b of the Magnetic Resonance Imaging mark 322, and the fourth felt portion 342 of the Velcro is mounted on the lower surface 321a of the Computed Tomography mark 321. During the usage, the first felt portion 331 and the second felt portion 332 of the Velcro are adapted for mounting the Magnetic Resonance Imaging mark 322 and the patch 310 to each other in the attaching manner, and the third felt portion 341 and the fourth felt portion 342 of the Velcro are adapted for mounting the Magnetic Resonance Imaging mark 322 and the Computed Tomography mark 321 to each other in the attaching manner. In other words, the patch 310, the Computed Tomography mark 321 and the Magnetic Resonance Imaging mark 322 are mounted to each other by the first and second demountable elements 330, 340. The Computed Tomography mark 321 can be made of metal material, high polymer material, ceramics material or combinations thereof. Also, the diameter of the Computed Tomography mark 321 must be more than 2 mm. The diameter of the Magnetic Resonance Imaging mark 322 must be more than 10 mm.

In another embodiment, when the Computed Tomography mark is made of titanium (Ti) metal material, high polymer material, ceramics material or combinations thereof, the Computed Tomography mark can be disposed between the Magnetic Resonance Imaging mark and the patch. Thus, the first demountable element can be mounted on an upper surface of the patch and/or a lower surface of the Computed Tomography mark. Also, the second demountable element can be mounted on an upper surface of the Computed Tomography mark and/or a lower surface of the Magnetic Resonance Imaging mark.

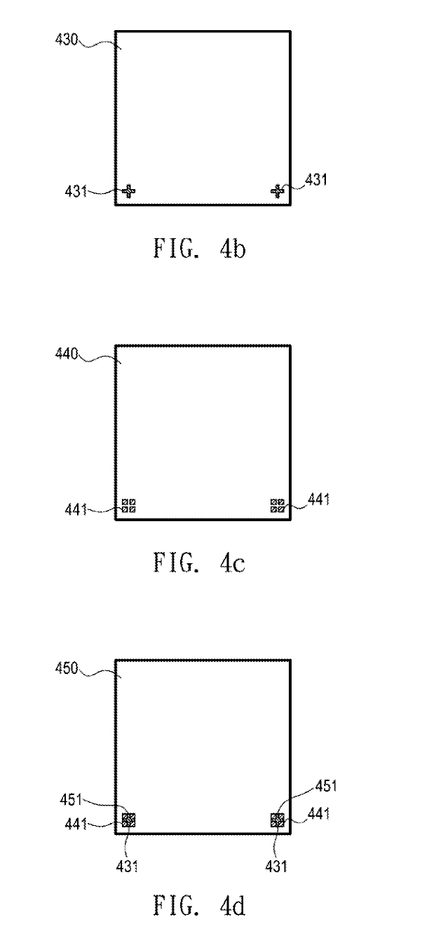

FIG. 4a is a schematic block diagram showing an image projecting system according to an embodiment of the present invention. FIG. 4b is a schematic view showing a Magnetic Resonance Imaging image of the present invention. FIG. 4c is a schematic view showing a Computed Tomography image of the present invention. FIG. 4d is a schematic view showing an overlapped image of the present invention. The image projecting system 400 includes an image overlapping device 410 and a projecting device 420. The image overlapping device 410 is adapted to overlap a Magnetic Resonance Imaging image 430 with a Computed Tomography image 440 so as to get an overlapped image. In this embodiment, the Magnetic Resonance Imaging image 430 has at least two images 431 of the Magnetic Resonance Imaging mark, and each image 431 of the Magnetic Resonance Imaging mark is a cross-shaped pattern. In this embodiment, the Computed Tomography image 440 has at least two images 441 of the Computed Tomography mark, and each image 441 of the Computed Tomography mark is four rectangular patterns. The overlapped image 450 is formed by overlapping the Magnetic Resonance Imaging image 430 with the Computed Tomography image 440. Also, the images 431 of the Magnetic Resonance Imaging mark are aligned with the images 441 of the Computed Tomography mark, i.e., the cross-shaped pattern is overlapped with the four rectangular patterns so as to form a square pattern 451.

The projecting device 420 is electrically connected to the image overlapping device 410 for projecting the overlapped image 450 on a skin surface of a patient, whereby a surgical doctor can quickly and certainly determine an operative route of a surgical operation by the vision together with the sense of hand touch.

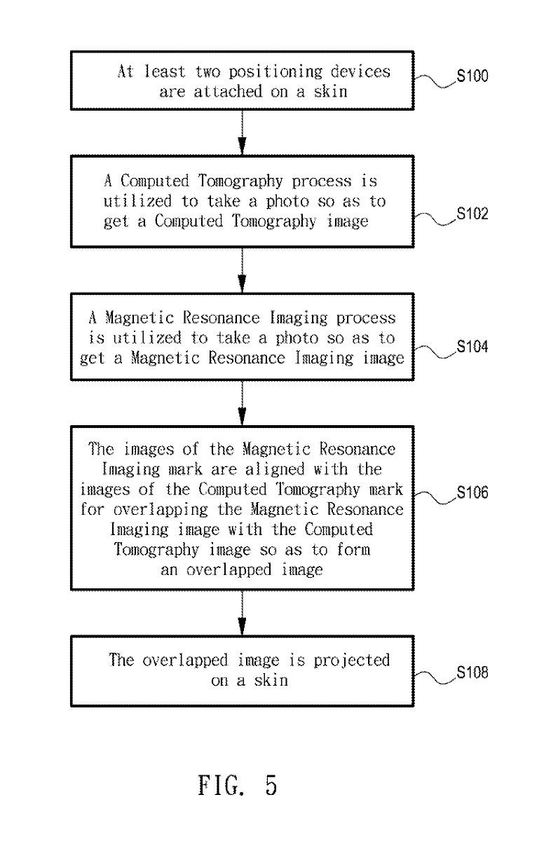

FIG. 5 is a flow diagram of a method for overlapping images according to an embodiment of the present invention. The method for overlapping the images includes the following steps.

In step S100, at least two positioning devices are attached on a skin. In this step, the positioning devices in the first, second and third embodiments are attached on the skin. In this embodiment, in order to overlap and position images subsequently, at least two positioning devices are attached on the skin. In other embodiment, symbols can be also marked on the skin by a marker pen, and replace the patches in the first, second and third embodiments. Then, the Magnetic Resonance Imaging mark and the Computed Tomography mark are mounted on the marked symbols of the skin in order.

In step S102, a Computed Tomography process is utilized to take a photo so as to get a Computed Tomography image. In this step, the material of the Computed Tomography mark can stop the light energy (e.g., X-radiation) emitted by the Computed Tomography process, and thus the Computed Tomography image 440 can include at least two images 441 of the Computed Tomography mark (shown in FIG. 4c).

In step S104, a Magnetic Resonance Imaging process is utilized to take a photo so as to get a Magnetic Resonance Imaging image. In this step, the Computed Tomography mark must be removed before the photo of the Magnetic Resonance Imaging process is taken, if the positioning device in the third embodiment is used, and the Computed Tomography mark of the positioning mark is not made of titanium (Ti) metal material (for example, the Computed Tomography mark of the positioning mark is made of typical metal material, e.g., steel, iron, copper, etc.). The reason that the Computed Tomography mark must be removed is the typical metal material can be magnetized because of the emitting of an electromagnetic wave, such that the photo of the Magnetic Resonance Imaging process cannot be taken. However, titanium (Ti) metal material cannot be magnetized during the emitting of the electromagnetic wave, and thus the photo of the Magnetic Resonance Imaging process can be taken directly. When the photo of the Magnetic Resonance Imaging process is taken, the rotational arrangement direction of hydrogen atoms in the human body and the Magnetic Resonance Imaging mark is changed because of the emitting of the electromagnetic wave, and then the resonance is generated. The electromagnetic wave released by the human body and the Magnetic Resonance Imaging mark is analyzed. Different electromagnetic wave is generated according to different tissue, and thus the relative location of the tissue in the human body and the Magnetic Resonance Imaging mark, whereby the Magnetic Resonance Imaging image of the inside human body can be finished, wherein the Magnetic Resonance Imaging image 430 can include at least two images 431 of the Magnetic Resonance Imaging mark (shown in FIG. 4b).

In step S106, the images of the Magnetic Resonance Imaging mark are aligned with the images of the Computed Tomography mark for overlapping the Magnetic Resonance Imaging image with the Computed Tomography image so as to form an overlapped image. Referring FIG. 4a simultaneously, in this step, the Magnetic Resonance Imaging image is overlapped with the Computed Tomography image by utilizing the image overlapping device 410 so as to form the overlapped image. The image 431 (shown in FIG. 4b) of the Magnetic Resonance Imaging mark and the image 441 (shown in FIG. 4c) of the Computed Tomography mark are acted as the positioning point by the image overlapping device 410, and then the image 431 of the Magnetic Resonance Imaging mark is aligned with the image 441 of the Computed Tomography mark, whereby the Magnetic Resonance Imaging image can be accurately overlapped with the Computed Tomography image so as to form the overlapped image 450 (shown in FIG. 4d).

In step S108, the overlapped image is projected on a skin. In this step, the positioning mark of the positioning device can be firstly removed, and only the patch located on the skin is kept. Then, the overlapped image 450 is projected to the skin by the image device 420. When the overlapped image 450 is projected, two square patterns 451 of the overlapped image 450 must be overlapped with the patches located on the skin so as to confirm that tissue structure (e.g., muscle, bones, organ, etc.) under the skin can be matched with the overlapped image 450. Thus, a surgical doctor can quickly and certainly determine an operative route of a surgical operation by directly utilizing the overlapped image 450 projected on the skin.

The positioning device, the image projecting system and the method for overlapping images according to the present invention can provide the surgical doctor with the medical requirement of preoperative simulated image and operative augmented reality of that the overlapped image and the patch located on the skin are overlapped. Thus, according to the surgical doctor, the surgical operation performed by watching the image in the screen can be replaced with the surgical operation performed by directly positioning and projecting the overlapped image on the skin of the human body, whereby the preoperative simulated image can be accurately projected to the real affected part of a patient's body in the surgical operation.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A positioning device applied to a Computed Tomography process and a Magnetic Resonance Imaging process, the positioning device comprising:
a patch; and
a positioning mark adapted to be mounted on the patch, and comprising a Computed Tomography mark and a Magnetic Resonance Imaging mark.

2. The positioning device according to claim 1, wherein:
the Computed Tomography mark comprises a receiving space; and
the Magnetic Resonance Imaging mark is located in the receiving space.

3. The positioning device according to claim 2, wherein the Computed Tomography mark is made of titanium (Ti) metal material, high polymer material, ceramics material or combinations thereof.

4. The positioning device according to claim 1, wherein the Magnetic Resonance Imaging mark is disposed between the Computed Tomography mark and the patch.

5. The positioning device according to claim 4, further comprising:
a first demountable element mounted on an upper surface of the patch and/or a lower surface of the Magnetic Resonance Imaging mark; and
a second demountable element mounted on an upper surface of the Magnetic Resonance Imaging mark and/or a lower surface of the Computed Tomography mark.

6. The positioning device according to claim 5, wherein:
the first demountable element comprises:
a first felt portion mounted on the upper surface of the patch; and
a second felt portion mounted on the lower surface of the Magnetic Resonance Imaging mark, wherein the first felt portion and the second felt portion are adapted for mounting the Magnetic Resonance Imaging mark and the patch to each other in the attaching manner; and
the second demountable element comprises:
a third felt portion mounted on the upper surface of the Magnetic Resonance Imaging mark; and
a fourth felt portion mounted on the lower surface of the Computed Tomography mark, wherein the third felt portion and the fourth felt portion are adapted for mounting the Magnetic Resonance Imaging mark and the Computed Tomography mark to each other in the attaching manner.

7. The positioning device according to claim 1, wherein the Computed Tomography mark is disposed between the Magnetic Resonance Imaging mark and the patch, and the Computed Tomography mark is made of titanium (Ti) metal material, high polymer material, ceramics material or combinations thereof.

8. The positioning device according to claim 7, further comprising:
a first demountable element mounted on an upper surface of the patch and/or a lower surface of the Computed Tomography mark; and
a second demountable element mounted on an upper surface of the Computed Tomography mark and/or a lower surface of the Magnetic Resonance Imaging mark.

9. The positioning device according to claim 1, further comprising:
a demountable element mounted on an upper surface of the patch and/or a lower surface of the positioning mark.

10. The positioning device according to claim 9, wherein the demountable element comprises:
a first felt portion mounted on an upper surface of the patch; and
a second felt portion mounted on a lower surface of the positioning mark, wherein the first felt portion and the second felt portion are adapted for mounting the positioning mark and the patch to each other in the attaching manner.

11. The positioning device according to claim 1, wherein the patch comprises a screw hole, the positioning mark further comprises a screw portion, and the positioning mark is mounted on the patch in a screwing manner.
